(19) United States
(12) Patent Application Publication
(10) Pub. No.: US 2024/0196526 A1
(43) Pub. Date: Jun. 13, 2024

(54) WIRING SUBSTRATE

(71) Applicant: IBIDEN CO., LTD., Ogaki (JP)

(72) Inventors: Toshiki FURUTANI, Ibi-gun (JP); Masashi KUWABARA, Ibi-gun (JP); Susumu KAGOHASHI, Ogaki (JP)

(73) Assignee: IBIDEN CO., LTD., Ogaki (JP)

(21) Appl. No.: 18/522,588

(22) Filed: Nov. 29, 2023

(30) Foreign Application Priority Data
Dec. 9, 2022 (JP) 2022-196885

(51) Int. Cl. H05K 1/02; H05K 1/03; H05K 1/11; H05K 3/16; H05K 3/18

(52) U.S. Cl. CPC H05K 1/0298; H05K 1/0373; H05K 1/111; H05K 1/115; H05K 3/16; H05K 3/188; H05K 2201/09827

(57) ABSTRACT

A wiring substrate includes insulating layers including inorganic particles and resin, conductor layers formed on first surfaces of the insulating layers, respectively, and including the outermost conductor layer and a conductor layer, and via conductors formed in the insulating layers such that the via conductors are connecting the conductor layers formed on the first surfaces of the insulating layers. The conductor layers are formed such that the outermost conductor layer includes first conductor pads positioned to mount a first component and second conductor pads positioned to mount a second component and that the conductor layer includes first wiring patterns connecting the first conductor pads and the second conductor pads, and the insulating layers are formed such that the first surfaces of the insulating layers are formed of the resin and do not have exposed surfaces of the inorganic particles.

### CROSS-REFERENCE TO RELATED APPLICATIONS

The present application is based upon and claims the benefit of priority to Japanese Patent Application No. 2022-196885, filed Dec. 9, 2022, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2019-83303 describes a wiring substrate that includes insulating layers for build-up. The entire contents of this publication are incorporated herein by reference.

### SUMMARY OF THE INVENTION

According to one aspect of the present invention, a wiring substrate includes insulating layers including inorganic particles and resin, conductor layers formed on first surfaces of the insulating layers, respectively, and including the outermost conductor layer and a conductor layer, and via conductors formed in the insulating layers such that the via conductors are connecting the conductor layers formed on the first surfaces of the insulating layers. The conductor layers are formed such that the outermost conductor layer includes first conductor pads positioned to mount a first component and second conductor pads positioned to mount a second component and that the conductor layer includes first wiring patterns connecting the first conductor pads and the second conductor pads, and the insulating layers are formed such that the first surfaces of the insulating layers are formed of the resin and do not have exposed surfaces of the inorganic particles.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is a plan view of the wiring substrate of FIG. 1;

FIG. 3 is an enlarged view of a portion (III) of FIG. 1;

FIG. 4 is a cross-sectional view illustrating a modified example of a wiring substrate according to an embodiment of the present invention;

FIG. 5A is a cross-sectional view illustrating an example of a manufacturing process of a wiring substrate according to an embodiment of the present invention;

FIG. 5B is a cross-sectional view illustrating an example of a manufacturing process of a wiring substrate according to an embodiment of the present invention;

FIG. 5C is a cross-sectional view illustrating an example of a manufacturing process of a wiring substrate according to an embodiment of the present invention;

FIG. 5D is a cross-sectional view illustrating an example of a manufacturing process of a wiring substrate according to an embodiment of the present invention;

FIG. 5E is a cross-sectional view illustrating an example of a manufacturing process of a wiring substrate according to an embodiment of the present invention;

FIG. 5F is a cross-sectional view illustrating an example of a manufacturing process of a wiring substrate according to an embodiment of the present invention;

FIG. 5G is a cross-sectional view illustrating an example of a manufacturing process of a wiring substrate according to an embodiment of the present invention;

FIG. 5H is a cross-sectional view illustrating an example of a manufacturing process of a wiring substrate according to an embodiment of the present invention;

FIG. 5I is a cross-sectional view illustrating an example of a manufacturing process of a wiring substrate according to an embodiment of the present invention;

FIG. 5J is a cross-sectional view illustrating an example of a manufacturing process of a wiring substrate according to an embodiment of the present invention; and

FIG. 6 is a cross-sectional view illustrating an example of a method for manufacturing an electronic component using a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### Wiring Substrate

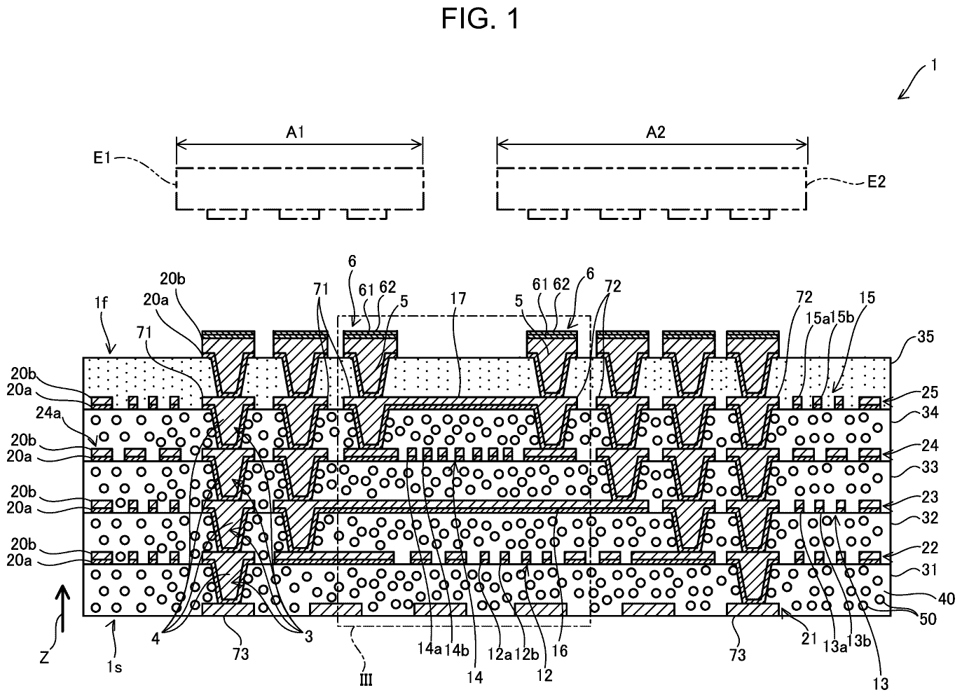

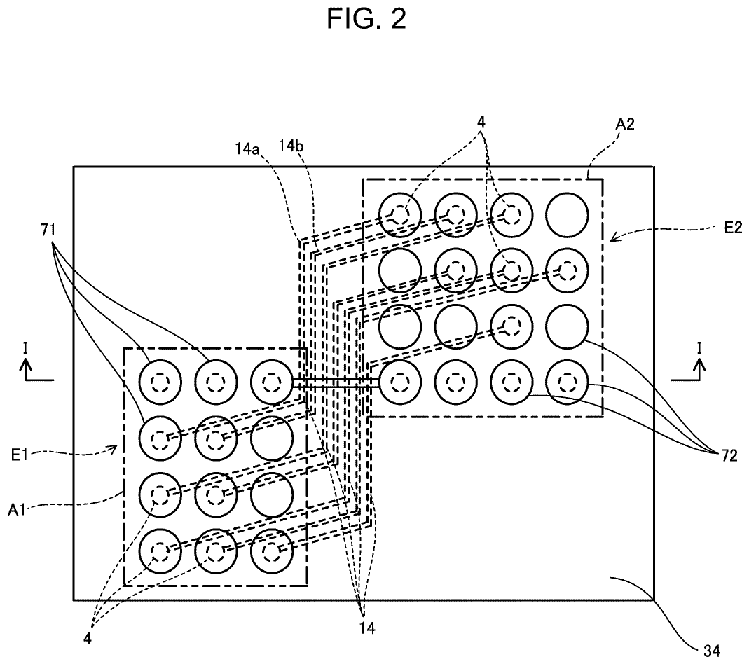

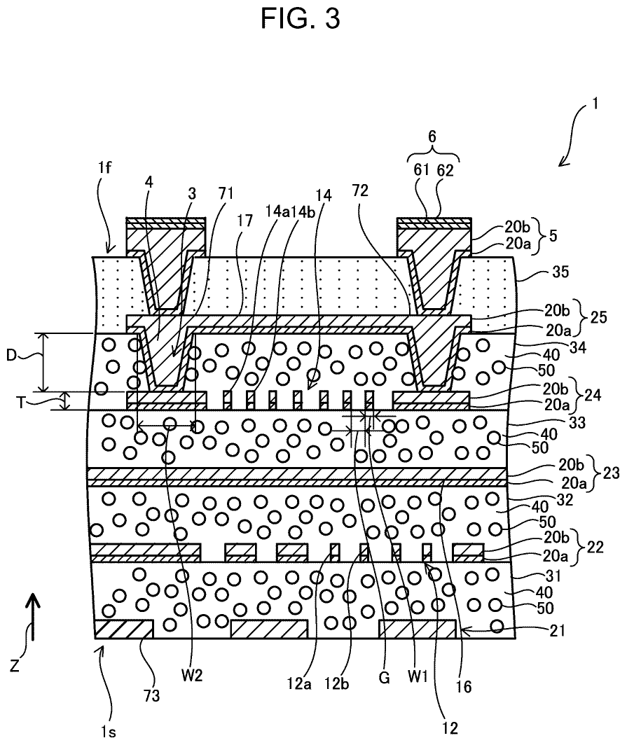

A wiring substrate according to an embodiment of the present invention is described with reference to the drawings. FIG. 1 illustrates a cross-sectional view of a wiring substrate 1, which is an example of the wiring substrate of the present embodiment. FIG. 2 illustrates an example of the wiring substrate 1 in a plan view, and FIG. 3 illustrates an enlarged view of a portion (III) of FIG. 1. The term “plan view” means viewing an object along a thickness direction of the wiring substrate 1. The wiring substrate 1 is merely an example of the wiring substrate of the embodiment. For example, a laminated structure of the wiring substrate of the embodiment, and the number of conductor layers and the number of insulating layers included in the wiring substrate of the embodiment are not limited to the laminated structure of the wiring substrate 1 of FIG. 1, and the number of conductor layers and the number of insulating layers included in the wiring substrate 1. Further, in the drawings to be referenced in the following description, in order to facilitate understanding of an embodiment to be disclosed, a specific portion may be depicted in an enlarged manner and it may be possible that structural elements are not depicted in precise proportions in terms of size or length relative to each other.

As illustrated in FIG. 1, the wiring substrate 1 has a first surface (1f), which is one of two surfaces (main surfaces) orthogonal to a thickness direction of the wiring substrate 1, and a second surface (1s) on the opposite side with respect to the first surface (1f). The wiring substrate 1 includes alternately laminated multiple conductor layers and multiple insulating layers. Specifically, the wiring substrate 1 illustrated in FIG. 1 includes alternately laminated conductor layers (21-25) and insulating layers (31-35). The wiring substrate 1 in the example of FIG. 1 is a so-called build-up wiring substrate manufactured by sequentially forming the conductor layers (21-25) and the insulating layers (31-35).

Among the conductor layers (21-25), the conductor layer 21 is formed on an outermost side on the second surface (1s) side of the wiring substrate 1. Surfaces of the conductor layer 21 other than a surface on the second surface (1s) side are covered by the insulating layer 31. Then, on a surface of the insulating layer 31 on the first surface (1f) side, in an order toward the first surface (1f), the conductor layer 22, the insulating layer 32, the conductor layer 23, the insulating layer 33, the conductor layer 24, the insulating layer 34, the conductor layer 25, and the insulating layer 35 are formed. The conductor layer 25 is an outermost conductor layer on the first surface (1f) side of the wiring substrate 1. The first surface (1f) of the wiring substrate 1 is mainly formed of a surface of the insulating layer 35, which covers the conductor layer 25, the surface facing an opposite direction with respect to the conductor layer 25. On the other hand, the second surface (1s) of the wiring substrate 1 is formed of surfaces of the conductor layer 21 and the insulating layer 31, the surfaces facing an opposite direction with respect to the conductor layer 22.

In the description of the embodiment, in the thickness direction (lamination direction) of the wiring substrate 1, the first surface (1f) side is also referred to as an “upper side” or “upper,” and the second surface (1s) side is also referred to as a “lower side” or “lower.” Further, for the conductor layers and the insulating layers, a surface facing the first surface (1f) side is also referred to as an “upper surface,” and a surface facing the second surface (1s) side is also referred to as a “lower surface.” The thickness direction of the wiring substrate of the embodiment is also referred to as a “Z direction.”

The wiring substrate 1 of the embodiment further includes via conductors 4 that penetrate the insulating layers (31-34) and connect the conductor layers (21-25). The wiring substrate 1 of FIG. 1 includes the multiple via conductors 4 that penetrate the insulating layers (31-34). The via conductors 4 penetrating the insulating layer 31 connect the conductor layer 21 and the conductor layer 22, the via conductors 4 penetrating the insulating layer 32 connect the conductor layer 22 and the conductor layer 23, the via conductors 4 penetrating the insulating layer 33 connect the conductor layer 23 and the conductor layer 24, and the via conductors 4 penetrating the insulating layer 34 connect the conductor layer 24 and the conductor layer 25. Each of the via conductors 4 is integrally formed with a conductor layer formed on an upper side of the each of the via conductors. The via conductors 4 each have a tapered shape that is reduced in width from the first surface (1f) side toward the second surface (1s) side of the wiring substrate 1. The “width” of each of the via conductors 4 is a longest distance between two points on an outer perimeter of a cross section (or an end surface) of the each of the via conductors 4 that is orthogonal to the Z direction.

The conductor layers (21-25) each include predetermined conductor patterns. In the example of FIG. 1, the conductor layer 25, which is the outermost conductor layer on the first surface (1f) side, includes multiple conductor pads 71 and multiple conductor pads 72, which are connected to components (a first component (E1) and a second component (E2) in the example of FIGS. 1 and 2) mounted on the wiring substrate 1 when the wiring substrate 1 is used. The conductor pads 71 are conductor pads (first conductor pads) on which the first component (E1) is mounted, and the conductor pads 72 are conductor pads (second conductor pads) on which the second component (E2), which is a separate component from the first component (E1), is mounted. The term “separate component” means that the first component (E1) and the second component (E2) are separate components, and do not necessarily mean that the first component (E1) and the second component (E2) are of different types. The first component (E1) and the second component (E2) may be of the same type or may be components having different functions from each other. The first component (E1) and the second component (E2) mounted on the wiring substrate 1 can be electronic components such as semiconductor integrated circuit devices such as microcomputers or memories.

The first surface (1f) of the wiring substrate 1, on which the first component (E1) and the second component (E2) are mounted, has a component mounting region (A1), which is a region where the first component (E1) is arranged, and a component mounting region (A2), which is a region where the second component (E2) is arranged. In the example of FIGS. 1 and 2, the multiple conductor pads 71 are all provided in the component mounting region (A1), and the multiple conductor pads 72 are all provided in the component mounting region (A2). In FIG. 2, depiction of the structural elements above the insulating layer 34 is omitted and only the conductor pads 71 and the conductor pads are illustrated.

The wiring substrate 1 of FIG. 1 further includes multiple conductor posts 5 formed on surfaces of the conductor pads 71 or the conductor pads 72. The conductor posts 5 penetrate the insulating layer 35 and protrude from the upper surface of the insulating layer 35, which forms the first surface (1f) of the wiring substrate 1. On the upper surface of the insulating layer 35, no conductor layer is formed and there are no conductors other than the conductor posts 5. By the conductor posts 5, the components (the first component (E1) and the second component (E2) in the example of FIG. 1) mounted on the wiring substrate 1 are connected to the conductor pads 71 or the conductor pads 72. Since the first component (E1) and the second component (E2) are connected to the wiring substrate via the conductor posts 5, it may be possible that the mounting of the components is facilitated and a short circuit between the conductor pads 71 or a short circuit between the conductor pads 72 is prevented.

On end surfaces of the conductor posts 5 on the opposite side with respect to the conductor layer 25, a functional layer 6 is formed that can function as a protective layer of the end surfaces of the conductor posts 5 and/or a bonding layer between the first component (E1) or the second component (E2) and the conductor posts 5. The functional layer 6 is formed of, for example, a plating film of nickel, tin, palladium, gold, or the like.

The conductor layer 25 includes a conductor pattern 17 and multiple wiring patterns 15 in addition to the conductor pads 71 and the conductor pads 72. As illustrated in FIG. 1, the conductor pattern 17 connects the conductor pads 71 and the conductor pads 72. Although not illustrated, the wiring patterns 15 are signal lines that connect any conductor pads included in any of the conductor layers (21-25) to propagate electrical signals.

The conductor layer 24 includes multiple wiring patterns 14, the conductor layer includes a conductor pattern 16 and multiple wiring patterns 13, and the conductor layer 22 includes multiple wiring patterns 12. Two ends of the conductor pattern 16 included in the conductor layer 23 are respectively connected to one conductor pad 71 and one conductor pad 72 via the via conductors 4. These conductor pad 71 and conductor pad are connected to each other via the conductor pattern 16. Similar to the wiring patterns 15, the multiple wiring patterns 14 included in the conductor layer 24, the multiple wiring patterns 13 included in the conductor layer 23, and the multiple wiring patterns 12 included in the conductor layer 22 are signal lines that each connect any conductor pads to propagate electrical signals.

The multiple wiring patterns 12 included in the conductor layer 22 include a pair wiring formed by a first signal wiring (12a) and a second signal wiring (12b). The second signal wiring (12b) may be provided adjacent to the first signal wiring (12a). Similarly, the multiple wiring patterns 13 included in the conductor layer 23 include a pair wiring formed by a first signal wiring (13a) and a second signal wiring (13b). The multiple wiring patterns 14 included in the conductor layer 24 include a pair wiring formed by a first signal wiring (14a) and a second signal wiring (14b). The multiple wiring patterns 15 included in the conductor layer 25 include a pair wiring formed by a first signal wiring (15a) and a second signal wiring (15b).

On the other hand, in the example of FIG. 1, the conductor layer 21, which is the outermost conductor layer on the second surface (1s) side of the wiring substrate 1, includes conductor pads 73. The conductor pads 73 are conductor pads (third conductor pads) that are connected to external conductors (not illustrated) of the wiring substrate 1. The external conductors connected to the conductor pads 73 can be, for example, electrodes of an electronic component such as a semiconductor integrated circuit device similar to the first component (E1) and the second component (E2). Without being limited to a semiconductor integrated circuit device, the conductor pads 73 can be connected to electrodes of any electronic component, or pads of a wiring substrate other than the wiring substrate 1 such as a motherboard of an electronic device, or any conductive mechanism elements, or the like.

In the example of FIG. 1, the conductor pads 71 of the conductor layer 25 and the conductor pads 73 of the conductor layer 21 are connected via multiple stacked via conductors 4 (so-called stacked via conductors). Similarly, the conductor pads 72 and the conductor pads 73 are connected via multiple stacked via conductors 4. Therefore, the conductor pads 71 and the conductor pads 72 are connected to the conductor pads 73 via a substantially shortest distance. Therefore, when the wiring substrate 1 is used, the first component (E1) and the second component (E2) can be connected via a short path to a member, such as a motherboard, connected to the conductor pads 73. Therefore, it is thought that intended electrical characteristics can be easily obtained. Different from the example of FIG. 1, it is also possible that only the conductor pads 71 or only the conductor pads 72 are connected to the conductor pads 73 via the so-called stacked via conductors, and it is also possible that none of the conductor pads (71, 72) are connected to the conductor pads 73.

In FIG. 2, the multiple wiring patterns 14 included in the conductor layer 24 are indicated using dashed lines. As illustrated in FIG. 2, each of the multiple wiring patterns extends between directly below one of the multiple conductor pads 71 and directly below one of the multiple conductor pads 72. Then, each of two ends of each of the wiring patterns 14 is connected via a via conductor 4 to a conductor pad 71 or a conductor pad 72. That is, one of the multiple conductor pads 71 and one of the multiple conductor pads 72 are connected to each other via one of the wiring patterns 14.

In this way, the multiple conductor layers (the conductor layers (21-25) in the example of FIG. 1) included in the wiring substrate 1 of the embodiment include a conductor layer that includes wiring patterns connecting the conductor pads 71 and the conductor pads 72 (the conductor layer 24 that includes the wiring patterns 14 in the example of FIGS. 1 and 2). In the description of the embodiment, wiring patterns such as the wiring patterns 14 that connect first conductor pads such as the conductor pads 71 on which the first component (E1) is mounted and second conductor pads such as the conductor pads 72 on which the second component (E2) is mounted are also appropriately referred to as “first wiring patterns” for distinction from other wiring patterns. Further, a conductor layer such as the conductor layer 24 that includes the “first wiring patterns” is also appropriately referred to as a “first conductor layer” for distinction from other conductor layers.

As described above, the conductor pattern 16 and the conductor pattern 17 also connect the conductor pads 71 and the conductor pads 72. The conductor patterns (16, 17) can each be a so-called solid pattern that functions as a so-called ground plane or power plane, or functions as a shield for the wiring patterns 14. However, it is also possible that that the conductor patterns (16, 17) are wiring patterns that propagate electrical signals, similar to the wiring patterns 14. When the conductor patterns (16, 17) are wiring patterns, the conductor patterns (16, 17) also can be “first wiring patterns.” The wiring patterns 12, the wiring patterns 13, and the wiring patterns 15 also may connect the conductor pads 71 and the conductor pads 72, and in this case, the wiring patterns (12, 13, 15) also can be “first wiring patterns.” Therefore, the conductor layers (22, 23, 25) also can each be a “first conductor layer.” That is, the wiring substrate of the embodiment can include one or more “first conductor layers” that include the “first wiring patterns.” Further, a “first conductor layer” can include one or more “first wiring patterns.”

In the wiring substrate of the embodiment, a surface (24a) of a “first conductor layer” (such as the conductor layer 24 of the wiring substrate 1) on the first surface (1f) side is a polished surface in a state of having been polished. Therefore, the surface (24a) can have, for example, a surface roughness lower than that of a plating film formed as it is by metal deposition. Therefore, it is thought that, in the wiring patterns 14 and the like included in the conductor layer 24, deterioration of signal transmission characteristics or an increase in voltage drop due to a substantial increase in conductor resistance due to a skin effect seen in transmission of high-frequency signals is unlikely to occur. For example, the polished surface of a “first conductor layer” such as the conductor layer 24 on the first surface (1f) side can have an arithmetic mean roughness of 0.3 μm or less. When such a surface roughness is obtained, it may be possible that a favorable effect regarding transmission characteristics described above can be obtained.

Further, the surface (24a), which is a polished surface, is likely to have a uniform height (for example, a distance from the second surface (1s)) over the entire conductor layer 24. Therefore, the via conductors 4 formed on the conductor layer 24 are likely to be aligned in height, and the conductor posts 5 formed thereon also are likely to be aligned in height. As a result, it is thought that the first component (E1) and/or the second component (E2) can be stably mounted on the wiring substrate 1. Further, when the surface (24a) is a polished surface, each of the wiring patterns 14 and the like is likely to have a substantially constant thickness over its entire length, and thus, a characteristic impedance of each of the wiring patterns 14 is unlikely to fluctuate. Therefore, it may be possible that a reflection loss in the wiring patterns 14 is suppressed.

As illustrated in FIG. 3, the wiring patterns 14 included in the conductor layer 24 of the wiring substrate 1 have a wiring width (W1) and a distance (G) between adjacent wiring patterns 14. In the present embodiment, a “first conductor layer” such as the conductor layer 24 that includes wiring patterns such as the wiring patterns 14 connecting the conductor pads 71 and the conductor pads 72 include wiring patterns that are arranged at a relatively fine pitch among the wiring patterns included in the wiring substrate of the embodiment. In the wiring substrate of the present embodiment, a minimum value of the wiring width (W1) of the wiring patterns included in a “first conductor layer” is 1 μm or more and 3 μm or less and a minimum value of the distance (G) between adjacent wiring patterns is 1 μm or more and 3 μm or less. That is, a “first conductor layer” includes wiring patterns that have a wiring width of 3 μm or less and a distance of 3 μm or less between adjacent wiring patterns. In the example of FIGS. 1-3, the wiring width (W1) of the wiring patterns 14, which are first wiring patterns, is 1 μm or more and 3 μm or less, and the distance (G) between adjacent wiring patterns 14 is 1 μm or more and 3 μm or less.

In the present embodiment, a “first conductor layer” such as the conductor layer 24 includes wiring patterns having such a fine minimum wiring width and a fine minimum inter-wiring distance, and in particular, the “first wiring patterns” such as the wiring patterns 14 have a fine minimum wiring width and a fine minimum inter-wiring distance. Therefore, it is thought that the first component (E1) and the second component (E2) are connected by multiple signal lines with small occupation areas. Therefore, it may be possible that the wiring substrate 1 of the embodiment can be realized smaller than a conventional wiring substrate. Further, in designing the wiring substrate of the embodiment having wiring patterns with such fine wiring width and inter-wiring distance between the conductor pads to be connected to components, it may be possible that a degree of freedom in arranging two components is high.

In addition, in the present embodiment, the “first wiring patterns” such as the wiring patterns 14, which can have such a fine wiring width, have a thickness (T) larger than the wiring width (W1). Therefore, in the present embodiment, the first wiring patterns have a relatively large aspect ratio ((the thickness (T) of the first wiring patterns)/(the width (W1) of the first wiring patterns)). Specifically, the “first wiring patterns” such as the wiring patterns 14 have an aspect ratio of 2.0 or more and 4.0 or less. The first wiring patterns having such an aspect ratio can have a low conductor resistance for a small wiring width. Therefore, it is thought that the wiring patterns 14 connecting the conductor pads 71 and the conductor pads 72 have low insertion loss. Therefore, it may be possible that signals can be propagated with little transmission loss between the first component (E1) and the second component (E2), that is, good transmission efficiency can be obtained. Further, it may be possible that in the signal lines connecting the first component (E1) and the second component (E2), a desired characteristic impedance can be easily obtained and insertion loss can be reduced.

In the example of FIGS. 1-3, the thickness (T) of the wiring patterns 14, which are first wiring patterns, that is, the thickness of the conductor layer 24, which is a first conductor layer, can be 4 μm or more and 7 μm or less. When such a thickness is obtained, it may be possible that the effect such as the reduction in insertion loss as described above can be obtained without significantly increasing the thickness of the wiring substrate of the embodiment.

As described above, in the present embodiment, the conductor layers (22-25) each can include wiring patterns such as the wiring patterns 14 arranged at a relatively fine pitch. Therefore, it may be possible that via conductors 4 arranged at a small pitch, that is, via conductors 4 each with a small width, are preferable. From this point of view, it may be possible that via conductors 4 with a large aspect ratio are preferable. In the wiring substrate 1 of the embodiment, the via conductors 4 can have an aspect ratio of, for example, 0.5 or more and 1.0 or less. It may be possible that wiring patterns such as the wiring patterns 14 arranged at a fine pitch can be connected to wiring patterns of a conductor layer different from the conductor layer including the wiring patterns arranged at a fine pitch, while maintaining a relatively fine pitch even at connection parts between the conductor layers. The aspect ratio of the via conductors 4 is (distance (D) in the Z direction between two conductor layers connected by a via conductor 4)/(width (W2) of the via conductor 4 at an interface with the conductor layer on the first surface (1f) side) illustrated in FIG. 3.

As described above, in the wiring substrate 1, the conductor layers (22, 23, 25) also can each be a “first conductor layer.” Therefore, for each of all the multiple conductor layers included in the wiring substrate 1 of the embodiment except for the outermost conductor layer on the second surface (1s) side (the conductor layer 21 in the example of FIGS. 1-3), the surface on the first surface (1f) side may be a polished surface. It may be possible that for each of the conductor layers, an effect such as good transmission characteristics as described above can be obtained. Further, as described above, the conductor layers (22, 23, 25) also can each include “first wiring patterns” similar to the wiring patterns 14 of the conductor layer 24. Therefore, all the multiple conductor layers included in the wiring substrate 1 of the embodiment except for the outermost conductor layer on the second surface (1s) side may each include wiring patterns having a wiring width of 1 μm or more and 3 μm or less and an aspect ratio of 2.0 or more and 4.0 or less. Further, all the conductor layers except for the outermost conductor layer on the second surface (1s) side may each include wiring patterns having a distance of 1 μm or more and 3 μm or less between adjacent wiring patterns. It may be possible that wiring patterns with small insertion loss can be obtained in each of the conductor layers, and in addition, the wiring substrate of the embodiment can be designed with a higher degree of freedom and can be realized in a smaller size than a conventional wiring substrate.

The insulating layers (31-34) are each an interlayer insulating layer interposed between two conductor layers. The insulating layers (31-34) are each formed of a resin and inorganic particles 50. The resin 40 is an insulating resin. Examples of the insulating resin include thermosetting resins such as epoxy resins, bismaleimide triazine resins (BT resins), or phenolic resins; and thermoplastic resins such as fluorine resins, liquid crystal polymers (LCP), fluoroethylene (PTFE) resins, polyester (PE) resins, and modified polyimide (MPI) resins. The inorganic particles 50 function as a filler. Examples of the inorganic particles 50 include silica particles and alumina particles. The insulating layers (31-34) may each also contain a reinforcing material (core material) such as a glass fiber (not illustrated). However, from a point of view of facilitating formation of wiring patterns arranged at a fine pitch, it may be preferable that a reinforcing material is not contained.

It is thought that, as the inorganic particles 50 contained in the insulating layers (31-34), an inorganic filler having small particle sizes (a particle size of an inorganic filler particle is a longest distance between two points on a surface of the inorganic filler particle) is preferable. The particle sizes of the inorganic particles 50 are preferably 1 μm or less. When the particle sizes of the inorganic particles 50 contained in each of the insulating layers are small, for example, even between wiring patterns arranged at a fine pitch, such as the wiring patterns 14, it may be possible that a short circuit failure due to a leak path or the like along the inorganic particles 50 is unlikely to occur. Further, it may be possible that small-sized via conductors 4 can be easily formed.

A surface (upper surface) on the first surface (1f) of each of the insulating layers (31-34) is formed only of the resin 40. No inorganic particles 50 are exposed from the upper surfaces of the insulating layers (31-34). The upper surfaces of the insulating layers (31-34) do not include surfaces of the inorganic particles 50. No unevenness is formed on the upper surfaces of the insulating layers (31-34). The upper surfaces of the insulating layers (31-34) are not roughened. The upper surfaces of the insulating layers (31-34) are formed smooth.

On the other hand, in the insulating layers (31-34), the inorganic particles 50 are exposed on inner wall surfaces of openings 3 for the via conductors 4. The inner wall surfaces of the openings 3 include surfaces of the inorganic particles 50. The inner wall surfaces of the openings 3 have unevenness. The inner wall surfaces of the openings 3 are formed of exposed surfaces of the resin 40 and exposed surfaces of the inorganic particles 50.

A thickness of each of the insulating layers (31-34) is two or more times a thickness of each of the conductor layers (22-25), which are respectively provided on the upper surfaces of the insulating layers (31-34). The thickness of each of the insulating layers (31-34) is a distance between the upper surface of the each of the insulating layers (31-34) and an upper surface of the conductor layer (21-24) directly below the each of the insulating layers (31-34). For example, the thickness of the insulating layer 34 is the distance between the upper surface of the insulating layer 34 and the upper surface of the conductor layer 24 (distance (D) in FIG. 3).

Further, in order to obtain good high-frequency signal transmission characteristics in the wiring patterns included in each of the conductor layers (21-25) included in the wiring substrate 1, insulating layers (31-34) having low dielectric constant and dielectric loss are preferred. For example, for each of the insulating layer (31-34), a relative permittivity is about 3.0 or more and 4.0 or less and a dielectric loss tangent is about 0.001 or more and 0.005 or less at a frequency of 5.8 GHz.

The insulating layer 35 covering the conductor layer 25 is an insulating layer that functions as a solder resist. The insulating layer 35 is formed of a material of which a main component or an additive is different from that of the insulating layers (31-34). For example, the insulating layer 35 may be formed using an epoxy resin or a polyimide resin or the like containing a photosensitive agent. In other examples, the insulating layer may be formed using the same insulating resin as the insulating layers (31-34).

The conductor layers (21-25), the via conductors 4, and the conductor posts 5 are formed, for example, using any metal such as copper or nickel.

In the example of FIG. 3, the conductor layer 21 is formed of, for example, a single-layer metal film formed of an electrolytic plating film. The conductor layer 21 is embedded in the insulating layer 31 and only a surface thereof on the second surface (1s) side is exposed. On the other hand, the conductor layers (22-25) and the conductor posts each include a seed layer (20a) and an electrolytic plating layer (20b) formed on the seed layer (20a). The electrolytic plating layer (20b) is formed entirely on the seed layer (20a), that is, on the first surface (1f) side of the wiring substrate 1. A surface of the electrolytic plating layer (20b) on the first surface (1f) side is a polished surface that each of the conductor layers (22-25) described above can have.

The seed layer (20a) is formed of a metal film (sputtering film) formed by sputtering. The electrolytic plating layer (20b) is formed of a metal film formed by electrolytic plating using the seed layer (20a) as a power feeding layer. For each conductor layer, the seed layer (20a) is interposed between the electrolytic plating layer (20b) and the insulating layer on the lower side of the conductor layer. When the seed layer (20a) is formed of a sputtering film, it may be possible that strong adhesion of the conductor layers (22-25) and the conductor posts 5 with respect to the insulating layers (31-35) can be obtained. Further, it may be possible that the conductor layers (22-25) and the conductor posts 5 each have a highly flat upper surface.

As illustrated in FIG. 3, the functional layer 6 also can have a multilayer structure. In the example of FIG. 3, the functional layer 6 includes a lower layer 61, which is directly formed on end surfaces (upper surfaces) of the conductor posts 5 on the opposite side with respect to the conductor layer 25, and an upper layer 62, which is formed on the lower layer 61. The upper layer 62 is formed of, for example, tin, palladium, gold, or an alloy thereof. The upper layer 62 functions as a protective film for the conductor posts 5, and/or as a bonding material between the conductor posts 5 and the first component (E1) or the second component (E2) (see FIG. 1). The lower layer 61 is formed of, for example, a metal with suitable properties, such as nickel, and can function as a barrier film between the upper layer 62 and the conductor posts 5 and/or a film for strengthening adhesion between the two.

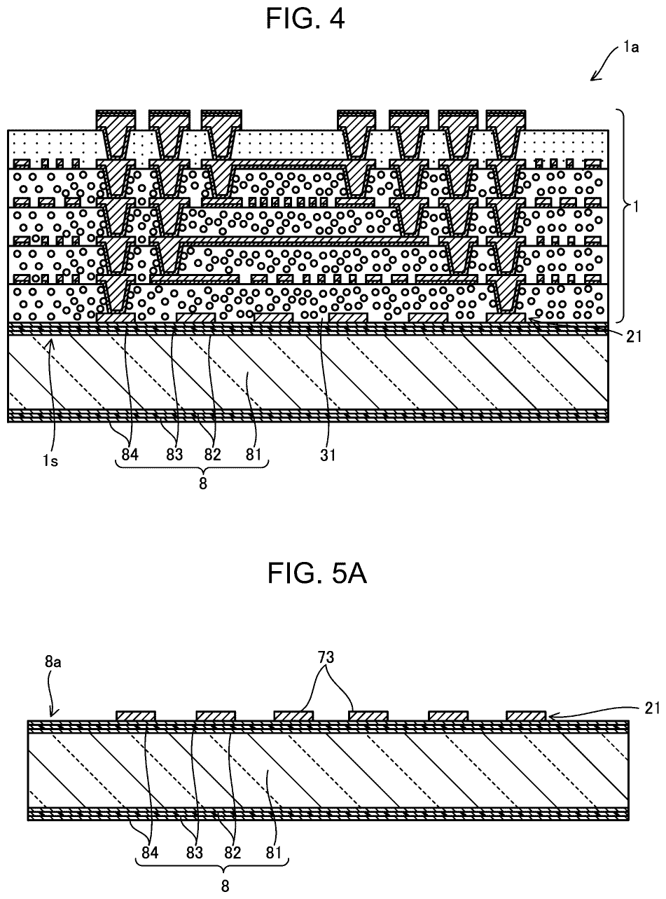

FIG. 4 illustrates a wiring substrate (1a), which is a modified example of the wiring substrate 1 of the present embodiment. FIG. 4 is a cross-sectional view of the wiring substrate (1a) at the same place as the cross-sectional view of the wiring substrate 1 illustrated in FIG. 1. As illustrated in FIG. 4, the wiring substrate (1a) includes a support 8 in addition to the wiring substrate 1 in the example of FIG. 1. The wiring substrate (1a) in the example of FIG. 4 has the same structure as the wiring substrate 1 in the example of FIG. 1, except that the support 8 is provided. Therefore, in FIG. 4, the same reference numeral symbols as those in FIG. 1 are attached to structural elements common to the structural elements of the wiring substrate 1 of FIG. 1 already described or are omitted as appropriate, and description of these structural elements is omitted.

As illustrated in FIG. 4, the support 8 is attached to the second surface (1s) of the wiring substrate 1 in the example of FIG. 1. In other words, the wiring substrate 1 is formed on a surface of the support 8. The support 8 in the example of FIG. 4 includes a base material 81, a first metal film layer 82 laminated on each of both sides of the base material 81, a release layer 83 formed on the first metal film layer 82, and a second metal film layer 84 laminated on the release layer 83.

The base material 81 is formed of, for example, an inorganic material such as glass or silicon having appropriate rigidity, or an organic material such as an epoxy resin with which a reinforcing material such as glass fiber is impregnated. The first metal film layer and the second metal film layer 84 can each be formed of any metal such as copper or a copper/titanium alloy. The release layer 83 is formed of any material that allows the first metal film layer 82 and the second metal film layer 84 to adhere to each other under a predetermined condition, and then, allows the adhered first metal film layer 82 and second metal film layer 84 to be separated from each other by being subjected to a specific treatment. For example, a material that softens or becomes brittle or loses its adhesiveness by being subjected to a specific treatment is used for the release layer 83. The release layer 83 can be formed of, for example, a thermoplastic adhesive that softens when heated, or a photosensitive adhesive that degrades when exposed to ultraviolet rays. The insulating layer 31 and the second metal film layer 84 are adhered, for example, by the adhesiveness of the insulating layer 31 itself when the insulating layer 31 is formed, and the conductor layer 21 and the second metal film layer 84 are adhered by metal-to-metal bonding when the conductor layer 21 is formed, for example, by plating.

The support 8 has a higher rigidity than the wiring substrate 1. Therefore, the wiring substrate 1 is supported by the support 8. Therefore, components such as the first component (E1) and the second component (E2) (see FIG. 1) can be stably mounted on the wiring substrate (1a) of the example of FIG. 4. Further, sealing of mounted components with a resin or the like can be easily performed. It is thought that, for example, a highly integrated and compact semiconductor integrated circuit device such as a multi-chip package device that includes the wiring substrate 1 can be easily manufactured. After component mounting or after sealing, the first metal film layer 82 and the second metal film layer 84 are separated from each other with the release layer 83 as a boundary, for example, through an appropriate treatment such as heating or ultraviolet irradiation described above. The second metal film layer 84 remaining on the wiring substrate 1 side can be removed, for example, by etching or the like. The support 8 illustrated in FIG. 4 is merely one example of a support that the wiring substrate (1a) of the present embodiment can include. A member of any material, structure and shape capable of supporting the wiring substrate 1 can be used as the support 8.

### Method for Manufacturing Wiring Substrate

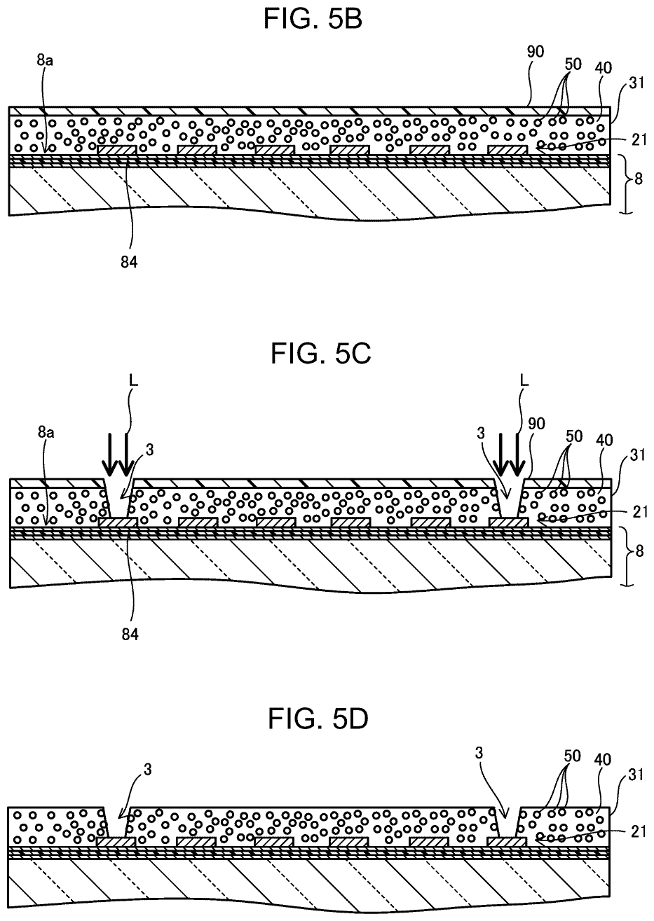

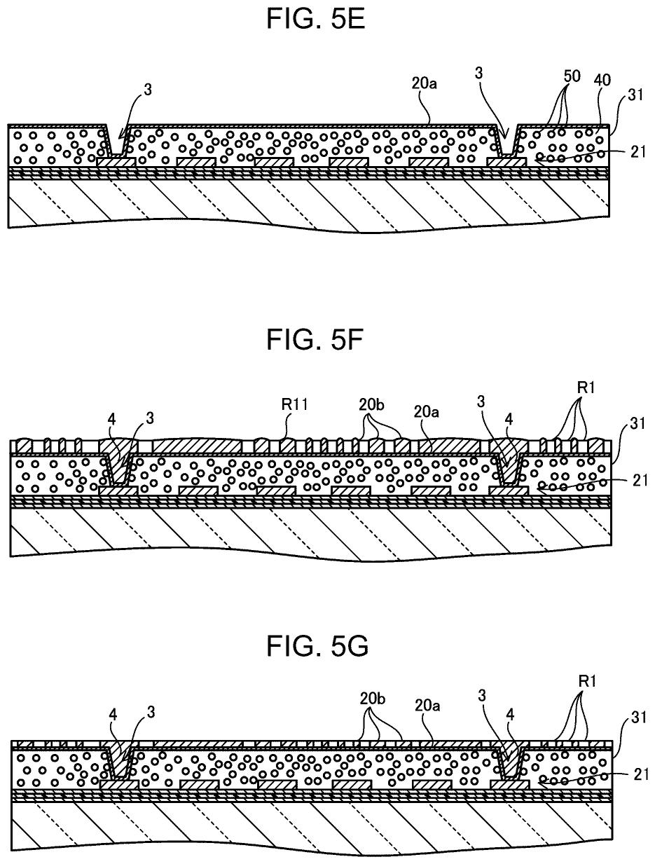

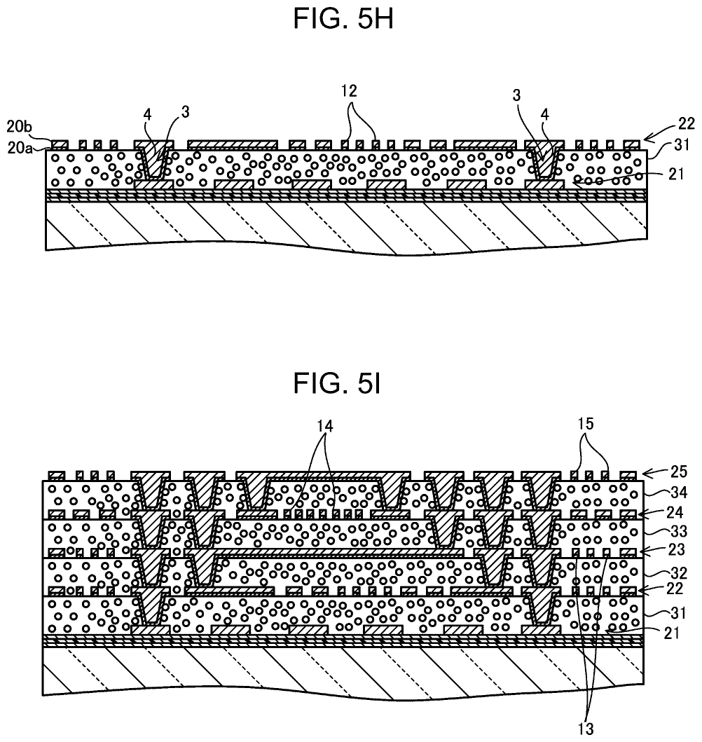

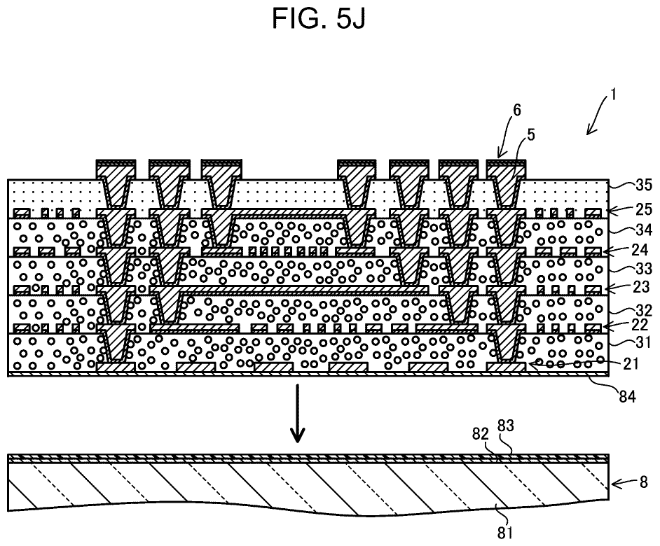

Next, with reference to FIGS. 5A-5J, an example of a method for manufacturing a wiring substrate according to an embodiment of the present invention is described using a case where the wiring substrate 1 illustrated in FIG. 1 is manufactured as an example. Unless there is a description different from the description provided above regarding the materials of the structural elements of the wiring substrate 1, the structural elements can be formed using any of the materials described above with respect to the structural elements.

As illustrated in FIG. 5A, the support 8 is prepared, and the conductor layer 21 is formed on a surface (8a) of the support 8. In the example illustrated in FIG. 5A, the support 8 illustrated in FIG. 4 referenced above is prepared. That is, in the example of FIG. 5A, as described above, the support 8 including the base material 81, the first metal film layer 82, the release layer 83, and the second metal film layer 84 is prepared.

The conductor layer 21 is formed, for example, by pattern plating using electrolytic plating. On the second metal film layer 84, which forms the surface (8a) of the support 8, a plating resist (not illustrated) is provided having openings corresponding to the formation positions of the conductor patterns such as the conductor pads 73 to be included in the conductor layer 21. Then, by electrolytic plating using the second metal film layer as a power feeding layer, a metal such as copper is deposited in the openings of the plating resist, and the conductor layer 21 is formed including conductor patterns formed of the deposited metal. After that, the plating resist is removed. Before the removal of the plating resist, the upper surface of the conductor layer 21 (the surface on the opposite side with respect to the support 8) may be polished, for example, using any method such as chemical mechanical polishing (CMP). It may be possible that even in the conductor layer 21, good transmission characteristics as described above can be obtained. When the polishing is performed, an upper surface portion of the plating resist before removal may be polished together with the upper surface of the conductor layer 21.

As illustrated in FIG. 5B, the insulating layer 31 and a protective film 90 are formed on the second metal film layer 84 and the conductor layer 21. A lower surface of the insulating layer 31 faces an upper surface of the second metal film layer 84. The protective film 90 is formed on an upper surface (surface on the first surface (1f) side) of the insulating layer 31. The upper surface of the insulating layer 31 is formed only of the resin 40. The inorganic particles 50 are not exposed from the upper surface of the insulating layer 31. The upper surface of the insulating layer 31 does not include surfaces of the inorganic particles 50. No unevenness is formed on the upper surface of the insulating layer 31. In FIG. 5B, and in FIGS. 5C-5J to be referenced below, depiction of the opposite side with respect to the surface (8a) side of the support 8 is omitted. However, also on the opposite side with respect to the surface (8a) side of the support 8, the conductor layer 21 may be formed in the process illustrated in FIG. 5A, and processing or formation of structural elements described with reference to FIGS. 5B-5J may be performed.

The protective film 90 completely covers the upper surface of the insulating layer 31. An example of the protective film 90 is a film formed of polyethylene terephthalate (PET). A release agent (not illustrated) is formed between the protective film 90 and the insulating layer 31.

As illustrated in FIG. 5C, laser (L) is irradiated from above the protective film 90. The laser (L) penetrates the protective film 90 and the insulating layer 31 at the same time. The openings 3 for the via conductors reaching to the pads of the conductor layer 21 are formed. The laser (L) is, for example, UV laser, or CO₂ laser. The pads are exposed from the openings 3. When the openings 3 are formed, the upper surface of the insulating layer is covered by the protective film 90. Therefore, when the openings 3 are formed, even when the resin scatters, adherence of the resin to the upper surface of the insulating layer is suppressed.

After that, the inside of the openings 3 is cleaned. By cleaning the inside of the openings 3, resin residues generated when the openings 3 are formed are removed. The cleaning of the inside of the openings 3 is performed using plasma. That is, the cleaning is performed with a dry process. The cleaning includes a desmear treatment. By the plasma, the resin 40 is selectively removed. The plasma removes the resin 40 faster than the inorganic particles 50. The inner wall surfaces of the openings 3 are roughened by the plasma.

By cleaning the inside of the openings 3, the inorganic particles 50 are exposed on the inner wall surfaces of the openings 3 (FIG. 5C). The inner wall surfaces of the openings 3 include surfaces of the inorganic particles 50. Unevenness is formed on the inner wall surfaces of the openings 3. On the other hand, the upper surface of the insulating layer 31 is covered by the protective film 90. The upper surface of the insulating layer 31 is not affected by plasma. The upper surface of the insulating layer 31 is formed only of the resin 40. The inorganic particles 50 are not exposed from the upper surface of the insulating layer 31. The upper surface of the insulating layer 31 does not include surfaces of the inorganic particles 50. No unevenness is formed on the upper surface of the insulating layer 31. The upper surface of the insulating layer 31 is formed smooth.

As illustrated in FIG. 5D, the protective film 90 is removed from the insulating layer 31. After the protective film 90 is removed, no roughening of the upper surface of the insulating layer 31 is performed.

As illustrated in FIG. 5E, the seed layer (20a) is formed on the upper surface of the insulating layer 31. The seed layer (20a) is formed by sputtering. The formation of the seed layer (20a) is performed with a dry process. The seed layer (20a) is also formed on the upper surfaces of the pads exposed from the openings 3 and on the inner wall surfaces of the openings 3. The seed layer (20a) is formed of copper. The seed layer (20a) may be formed of nickel. When the seed layer (20a) is formed by sputtering, it may be possible that a seed layer (20a) exhibiting high adhesion with the insulating layer 31 is formed. A portion of the seed layer (20a) can be the seed layer (20a) of the conductor layer 22 formed on the insulating layer 31 (see FIG. 3).

As illustrated in FIG. 5F, a plating resist (R1) having openings (R11) is provided on the seed layer (20a). The plating resist (R1) is formed, for example, by laminating a dry film resist onto the seed layer (20a), and the openings (R11) are formed, for example, using a photolithography technology. The openings (R11) are formed in patterns corresponding to the conductor patterns to be included in the conductor layer 22 (see FIG. 3) formed on the insulating layer 31.

The conductor patterns such as the wiring patterns 12 (see FIG. 3) included in the conductor layer 22 may have a wiring width of 3 μm or less, as described above. The openings (R11) are formed to have an opening width corresponding to the wiring width of the conductor patterns such as the wiring patterns 12 to be formed in the openings (R11). Further, as described above, the wiring patterns of the conductor layer 22 may have an aspect ratio of 2.0 or more and 4.0 or less. Therefore, in the method illustrated in FIG. 5F, preferably, the plating resist (R1) is formed having a thickness (height) equal to or greater than the thickness (height) of the wiring patterns that satisfies the aspect ratio of the wiring patterns to be formed.

An electrolytic plating layer (20b) formed of, for example, copper or nickel or the like is formed in the openings (R11) of the plating resist (R1) by electrolytic plating using the seed layer (20a) as a power feeding layer. A portion of the electrolytic plating layer (20b) can be the electrolytic plating layer (20b) of the conductor layer 22 formed on the insulating layer 31 (see FIG. 3). The via conductors 4 are formed in the openings 3 of the insulating layer 31. As in the example of FIG. 5F, the electrolytic plating layer (20b) may be formed to entirely fill the openings (R11) and further have a curved upper surface protruding upward from the upper surface of the plating resist (R1). It may be possible that conductor patterns with desired thickness and aspect ratio can be more reliably formed.

As illustrated in FIG. 5G, an upper-side portion of the electrolytic plating layer (20b) is removed by polishing. At least a portion of the electrolytic plating layer (20b) protruding from the upper surface of the plating resist (R1) is removed. The electrolytic plating layer (20b) is polished until a total thickness of the seed layer (20a) and the electrolytic plating layer (20b) reaches a thickness required for the conductor layer 22 (see FIG. 5E) formed on the insulating layer 31, for example, a thickness of 7 μm or less. As in the example of FIG. 5D, an upper-side portion of the plating resist (R1) may also be removed along with the portion of the electrolytic plating layer (20b). The polishing of the electrolytic plating layer (20b) is performed, for example, using any method such as CMP. As a result of the polishing, the upper surface of the electrolytic plating layer (20b) can have an arithmetic mean roughness of 0.3 μm or less.

After the polishing of the electrolytic plating layer (20b), the plating resist (R1) is removed. Further, a portion of the seed layer (20a) that is not covered by the electrolytic plating layer (20b) is removed, for example by quick etching or the like.

As a result, as illustrated in FIG. 5H, the conductor layer 22 including predetermined conductor patterns, such as the wiring patterns 12, separated from each other is obtained.

As illustrated in FIG. 5I, on the insulating layer 31 and the conductor layer 22, the Insulating layers (32-34) and the conductor layers (23-25) are alternately formed. The insulating layers (32-34) can each be formed, for example, using the same method as the method for forming the insulating layer 31. Further, the conductor layers (23-25) can each be formed, for example, using the same method as the method for forming the conductor layer 22. The conductor layers (23-25) are respectively formed using plating resists, such as the plating resist (R1) (see FIG. 5C) for the conductor layer 22, having openings corresponding to the conductor patterns, such as the wiring patterns (13-15), to be included in the conductor layers.

As illustrated in FIG. 5J, the insulating layer 35 is formed on the conductor layer 25 and the insulating layer 34. The insulating layer 35 is an insulating layer that functions as a solder resist. The insulating layer 35 is formed using a method such as spraying or curtain coating using an epoxy resin or polyimide resin or the like containing a photosensitive agent. The conductor posts 5 (see FIG. 5J) are formed. The conductor posts 5 may be formed, for example, using a method for forming a conductor layer, such as a semi-additive method. The formation of the conductor posts 5 includes polishing similar to the method for forming the conductor layer 22 described above.

The functional layer 6 is formed on the conductor posts 5. The functional layer 6 is formed, for example, by electrolytic plating. For example, a metal film of one or more layers formed of nickel, tin, palladium, gold, or the like is formed as the functional layer 6. The electrically isolated conductor posts 5 and functional layers 6 are obtained.

The support 8 is removed. For example, in a state in which the adhesiveness of the release layer 83 provided in the support 8 is lost or the release layer 83 itself is softened due to heating or ultraviolet irradiation or the like, the base material 81 and the first metal film layer 82 are pulled apart from the second metal film layer 84. After that, the second metal film layer 84 is removed by etching or the like. The surfaces of the conductor layer and the insulating layer 31 on the opposite side with respect to the conductor layer 22 are exposed. Through the above processes, the wiring substrate 1 of the example of FIG. 1 is completed.

When the wiring substrate (1a) illustrated in FIG. 4 is manufactured, the wiring substrate (1a) is completed through the processes up to forming the insulating layer 35, the conductor posts 5, and the functional layer 6 on the conductor layer 25 and the insulating layer 34.

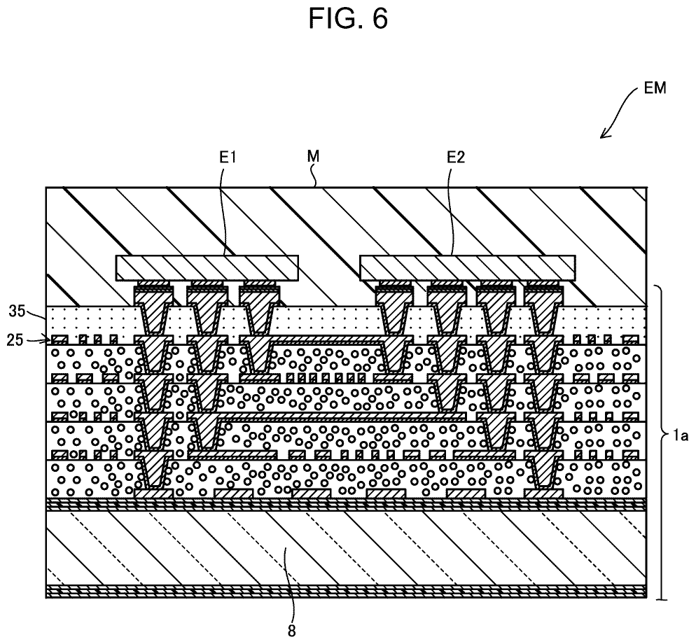

FIG. 6 illustrates an example of a state in a manufacturing process of an electronic component (a multi-chip package device) using the wiring substrate (1a) illustrated in FIG. 4. As illustrated in FIG. 6, in a manufacturing process of a multi-chip package device (EM), the first component (E1) and the second component (E2), which are, for example, microcomputers, memories, or the like, are mounted on the wiring substrate (1a) by a reflow treatment, flip-chip bonding, or the like. That is, the first component (E1) and the second component (E2) are mounted on the wiring substrate (1a) with the support 8 still provided. Since the conductor layers such as the conductor layer 25 and the insulating layers such as the insulating layer 35 are supported by the support 8, the first component (E1) and the second component (E2) can be mounted in a stable state. Therefore, it is thought that the first component (E1) and the second component (E2) can be connected to the wiring substrate (1a) with good quality and high reliability.

In the example of FIG. 6, the first component (E1) and the second component (E2) are further sealed with a mold resin (M) containing an epoxy resin or the like. The first component (E1) and the second component (E2) are sealed, for example, by transfer molding or compression molding. This sealing process can also be performed in the state in which the wiring substrate (1a) is provided with the support 8. Therefore, it is thought that handling of the wiring substrate (1a) with the components already mounted during the sealing process is easy, and the first component (E1) and the second component (E2) are sealed in a stable state with little movement of the wiring substrate (1a) in a molding machine. Therefore, it is thought that a defect related to the resin sealing is less likely to occur.

In the wiring substrates (1, 1a) (FIGS. 1 and 4) of the embodiment, the surfaces on the first surface (1f) side (the upper surfaces) of the insulating layers (31-34) are formed of the resin 40. No inorganic particles 50 are exposed from the upper surfaces of the insulating layers (31-34). No unevenness is formed on the upper surfaces of the insulating layers (31-34). An increase in standard deviation of the relative permittivity in portions near the upper surfaces of the insulating layers (31-34) is suppressed. The relative permittivity of the upper surfaces of the insulating layers (31-34) does not significantly vary depending on a location. Even when the multiple wiring patterns 12 (13, 14, 15) included in the conductor layer 22 (23, 24, 25) are in contact with the upper surface of the insulating layer 31 (32, 33, 34), a difference in propagation speed of an electrical signal between two adjacent wiring patterns 12 (13, 14, 15) can be reduced. That is, a difference in propagation speed of an electrical signal between the first signal wiring (12a) (13a, 14a, 15a) and the second signal wiring (12b) (13b, 14b, 15b) can be reduced. Therefore, in the wiring substrates (1, 1a) of the embodiment, noise is suppressed. Even when the first component (E1) and the second component (E2), which are logic ICs, are mounted on the wiring substrates (1, 1a) of the embodiment, data transmitted via the first signal wiring (12a) (13a, 14a, 15a) and data transmitted via the second signal wiring (12b) (13b, 14b, 15b) arrive at a logic IC substantially without delay. Malfunction of a logic IC can be suppressed. Even when a length of the first signal wiring (12a) (13a, 14a, 15a) and a length of the second signal wiring (12b) (13b, 14b, 15b) are 5 mm or more, a difference in propagation speed can be reduced. Even when the length of the first signal wiring (12a) (13a, 14a, 15a) and the length of the second signal wiring (12b) (13b, 14b, 15b) are 10 mm or more and 20 mm or less, malfunction of a logic IC can be suppressed. High quality wiring substrates (1, 1a) are provided.

In the wiring substrates (1, 1a) of the embodiment (FIGS. 1 and 4), the thickness of each of the insulating layers (31-34) is two or more times the thickness of each of the conductor layers (22-25), which are respectively provided on the upper surfaces of the insulating layers (31-34). It is thought that, when the wiring substrates (1, 1a) are subjected to heat cycles, a stress applied between the inner wall surfaces of the openings 3 and the via conductors 4 is greater than a stress applied between the conductor layers (22-25) and the upper surfaces of the insulating layers (31-34). Further, the inner wall surfaces of the openings 3 have unevenness. Therefore, adhesion strength between the inner wall surfaces of the openings 3 and the via conductors 4 is higher than adhesion strength between the conductor layers (22-25) and the upper surfaces of the insulating layers (31-34). The via conductors 4 are unlikely to peel off from the insulating layers (31-34). The conductor layers (22-25) are unlikely to peel off from the insulating layers (31-34).

In the wiring substrates (1, 1a) of the embodiment (FIGS. 1 and 4), the seed layer (20a) of the conductor layers (22-25) is formed by sputtering (FIG. 5E). Particles forming the seed layer (20a) collide perpendicularly with the upper surfaces of the insulating layers (31-34). Therefore, adhesion strength between the insulating layers (31-34) and the seed layer (20a) is high. On the other hand, particles forming the seed layer (20a) obliquely collide with the inner wall surfaces of the openings 3. However, the inner wall surfaces of the openings 3 have unevenness. Therefore, adhesion strength between the seed layer (20a) and the inner wall surfaces of the openings 3 is high. Even when the insulating layers (31-34) have no unevenness and the inner wall surfaces of the openings have unevenness, a difference between the adhesion strength between the conductor layers (22-25) and the upper surfaces of the insulating layers (31-34) and the adhesion strength between the via conductors 4 and the inner wall surfaces of the openings 3 can be reduced. A stress is unlikely to concentrate at an interface between the conductor layers (22-25) and the upper surfaces of the insulating layers (31-34). A stress is unlikely to concentrate at an interface between the via conductors 4 and the inner wall surfaces of the openings 3. Even when the wiring substrates (1, 1a) are subjected to heat cycles, the via conductors 4 are unlikely to peel off from the insulating layers (31-34). High quality wiring substrates (1, 1a) are provided.

The wiring substrate of the embodiment is not limited to those having the structures illustrated in the drawings and those having the structures, shapes, and materials exemplified herein. As described above, the wiring substrate of the embodiment can include any number of conductor layers and insulating layers. Wiring patterns (first wiring patterns) that connect conductor pads on which mounting components are mounted can be formed in one or more conductor layers. The conductor posts 5 and the functional layer 6 included in the wiring substrate 1 illustrated in FIG. 1 are not necessarily provided in the wiring substrate of the embodiment. The support 8 illustrated in FIG. 4 and the like does not necessarily have the structure illustrated in FIG. 4 and the like. The support 8 is not particularly limited in structure or material as long as the support 8 can support the conductor layers and the insulating layers included in the wiring substrate of the embodiment with required stability at least during a manufacturing process and can be intentionally removed at a desired time.

Japanese Patent Application Laid-Open Publication No. 2019-83303 describes a wiring substrate that includes insulating layers for build-up. Examples of the insulating layers for build-up include a first insulating layer and a second insulating layer. According to Japanese Patent Application Laid-Open Publication No. 2019-83303, insulating particles are dispersed in a thermosetting resin. According to Japanese Patent Application Laid-Open Publication No. 2019-83303, the insulating particles include partially exposed particles. In the present specification, partially exposed particles are referred to as exposed particles.

The technology of Japanese Patent Application Laid-Open Publication No. 2019-83303 has exposed particles. Therefore, it is thought that an upper surface of the first insulating layer in the patent document is formed of a resin forming the insulating layers for build-up and exposed surfaces of the exposed particles. A first wiring conductor is formed on the upper surface of the first insulating layer. It is thought that there is a difference in relative permittivity between the insulating particles and the resin forming the insulating layers for build-up. It is thought that it is difficult to uniformly disperse the exposed particles. It is thought that it is difficult to make areas of exposed portions of the exposed particles the same. Therefore, it is thought that the relative permittivity of the upper surface of the first insulating layer varies depending on a location. When the first wiring conductor includes two signal wirings, it is thought that there is a large difference in propagation speed between a signal transmitted through one signal wiring and a signal transmitted through the other signal wiring. It is thought that, when a wiring substrate including multiple signal wirings is manufactured using the technology of Japanese Patent Application Laid-Open Publication No. 2019-83303, a large amount of noise is generated.

A wiring substrate according to an embodiment of the present invention has a first surface and a second surface on the opposite side with respect to the first surface and includes: alternately laminated multiple conductor layers and multiple insulating layers; and via conductors that are formed in openings provided in the multiple insulating layers and connect the multiple conductor layers. Among the multiple conductor layers, an outermost conductor layer on the first surface side includes first conductor pads on which a first component is mounted and second conductor pads on which a second component is mounted. The multiple conductor layers include a first conductor layer that includes first wiring patterns connecting the first conductor pads and the second conductor pads. The multiple insulating layers are formed of inorganic particles and a resin. Surfaces of the multiple insulating layers on the first surface side covered by the multiple conductor layers are formed of the resin.

In a wiring substrate according to an embodiment of the present invention, the surfaces of the multiple insulating layers on the first surface side are formed of the resin. The surfaces of the insulating layers on the first surface side are formed only of the resin The surfaces of the insulating layers on the first surface side do not include surfaces of the inorganic particles. An increase in standard deviation of the relative permittivity in portions near the surfaces of the insulating layers on the first surface side is suppressed. The relative permittivity of the surfaces of the insulating layers on the first surface side is substantially uniform. A difference in propagation speed of an electrical signal between signal wirings included in the conductor layers formed on the insulating layers can be reduced. In the wiring substrate of the embodiment, noise is suppressed.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a plurality of insulating layers comprising inorganic particles and resin;
a plurality of conductor layers formed on first surfaces of the plurality of insulating layers, respectively, and including an outermost conductor layer and a conductor layer; and
a plurality of via conductors formed in the plurality of insulating layers such that the plurality of via conductors is connecting the plurality of conductor layers formed on the first surfaces of the insulating layers,
wherein the plurality of conductor layers is formed such that the outermost conductor layer includes a plurality of first conductor pads positioned to mount a first component and a plurality of second conductor pads positioned to mount a second component and that the conductor layer includes a plurality of first wiring patterns connecting the first conductor pads and the second conductor pads, and the plurality of insulating layers is formed such that the first surfaces of the insulating layers are formed of the resin and do not have exposed surfaces of the inorganic particles.

2. The wiring substrate according to claim 1, wherein the plurality of insulating layers is formed such that the insulating layers have a plurality of openings in which the via conductors are formed and that the openings have inner wall surfaces having the resin and exposed surfaces of the inorganic particles.

3. The wiring substrate according to claim 1, wherein the plurality of insulating layers is formed such that a thickness of each of the insulating layers is two or more times a thickness of each of the conductor layers.

4. The wiring substrate according to claim 1, wherein the plurality of conductor layers is formed such that each of the conductor layers includes a sputtered seed layer and an electrolytic plating layer formed on the sputtered seed layer.

5. The wiring substrate according to claim 1, wherein the plurality of conductor layers is formed such that the plurality of conductor layers includes a pair wiring comprising a first signal wiring and a second signal wiring.

6. The wiring substrate according to claim 1, wherein the plurality of insulating layers is formed such that the first surfaces are formed only of the resin.

7. The wiring substrate according to claim 1, wherein the plurality of conductor layers is formed such that the conductor layer has a plurality of wiring patterns having a minimum wiring width of 3 μm or less and a minimum inter-wiring distance of 3 μm or less.

8. The wiring substrate according to claim 1, wherein the plurality of conductor layers is formed such that an aspect ratio of the first wiring patterns in the conductor layer is in a range of 2.0 to 4.0.

9. The wiring substrate according to claim 1, wherein the plurality of conductor layers is formed such that the first wiring patterns in the conductor layer has a wiring width of 3 μm or less and an inter-wiring distance of 3 μm or less.

10. The wiring substrate according to claim 11, wherein the plurality of conductor layers is formed such that the first wiring patterns in the conductor layer has a thickness of 3 μm or less.

11. The wiring substrate according to claim 1, wherein the plurality of via conductors is formed such that an aspect ratio of the via conductors is in a range of 0.5 to 1.0.

12. The wiring substrate according to claim 1, further comprising:
a support attached to the plurality of insulating layers on an opposite side with respect to the outermost conductor layer of the conductor layers.

13. The wiring substrate according to claim 1, wherein the plurality of conductor layers includes a second outermost conductor layer on an opposite with respect to the outermost conductor layer such that the second outermost conductor layer includes a plurality of third conductor pads positioned to connect a plurality of external conductors, and the plurality of via conductors includes a plurality of stacked via structures formed such that at least one of the plurality of first conductor pads and the plurality of second conductor pads is connected to the plurality of third conductor pads via the plurality of stacked via conductors of the via conductors.

14. The wiring substrate according to claim 2, wherein the plurality of insulating layers is formed such that a thickness of each of the insulating layers is two or more times a thickness of each of the conductor layers.

15. The wiring substrate according to claim 2, wherein the plurality of conductor layers is formed such that each of the conductor layers includes a sputtered seed layer and an electrolytic plating layer formed on the sputtered seed layer.

16. The wiring substrate according to claim 2, wherein the plurality of conductor layers is formed such that the plurality of conductor layers includes a pair wiring comprising a first signal wiring and a second signal wiring.

17. The wiring substrate according to claim 2, wherein the plurality of insulating layers is formed such that the first surfaces are formed only of the resin.

18. The wiring substrate according to claim 2, wherein the plurality of conductor layers is formed such that the conductor layer has a plurality of wiring patterns having a minimum wiring width of 3 μm or less and a minimum inter-wiring distance of 3 μm or less.

19. The wiring substrate according to claim 2, wherein the plurality of conductor layers is formed such that an aspect ratio of the first wiring patterns in the conductor layer is in a range of 2.0 to 4.0.

20. The wiring substrate according to claim 2, wherein the plurality of conductor layers is formed such that the first wiring patterns in the conductor layer has a wiring width of 3 μm or less and an inter-wiring distance of 3 μm or less.
